(19) United States
(12) Patent Application Publication
(10) Pub. No.: US 2018/0211819 A1
(43) Pub. Date: Jul. 26, 2018

(54) PARTICLE TRAP FOR SPUTTERING COIL AND METHOD OF MAKING

(71) Applicant: Honeywell International Inc., Morris Plains, NJ (US)

(72) Inventors: James L. Koch, Newman Lake, WA (US); Andrew N.A. Wragg, Cheshire (GB)

(21) Appl. No.: 15/819,352

(22) Filed: Nov. 21, 2017

Related U.S. Application Data
(60) Provisional application No. 62/448,752, filed on Jan. 20, 2017.

(51) Int. Cl. H01J 37/32; C23C 14/34

(52) U.S. Cl. CPC H01J 37/32458; H01J 37/32541; C23C 14/34

(57) ABSTRACT

Disclosed herein is a sputtering chamber component comprising a particle trap, the particle trap comprising a patterned macrotexture formed on at least a portion of a surface of the sputtering chamber component. The patterned macrotexture has indentations having a depth and is arranged in a repeating pattern. The patterned macrotexture has first threads extending in a first direction, the first threads forming side walls separating adjacent indentations in a second direction. The patterned macrotexture has second threads extending in the second direction. The second direction is at an angle of greater than 0 and less than 180 degrees to the first direction, the second threads forming side walls separating adjacent indentations in the first direction. The patterned macrotexture has a random pattern microtexture formed on the patterned macrotexture; the microtexture has a height less than the depth of the indentations.

### CROSS-REFERENCE TO RELATED APPLICATION

This application claims priority to Provisional Application No. 62/448,752, filed Jan. 20, 2017, which is herein incorporated by reference in its entirety.

### TECHNICAL FIELD

The present disclosure relates to sputtering chamber components having particle traps used in physical vapor deposition apparatuses. More particularly, the present disclosure relates to sputter traps with reduced particles and methods of making the same.

### BACKGROUND

Deposition methods are used in forming films of material across substrate surfaces. Deposition methods can be used, for example, in semiconductor device fabrication processes to form layers ultimately used in making integrated circuits and devices. One example of a deposition method is physical vapor deposition (PVD). PVD methodologies may include sputtering processes. Sputtering includes forming a target of a material which is to be deposited, and providing the target as a negatively charged cathode proximate to a strong electric field. The electric field is used to ionize a low pressure inert gas and form a plasma. Positively charged ions in the plasma are accelerated by the electric field toward the negatively charged sputtering target. The ions impact the sputtering target, and thereby eject target material. The ejected target material is primarily in the form of atoms or groups of atoms, and can be used to deposit thin, uniform films on substrates placed in the vicinity of the target during the sputtering process.

It is desirable to develop components for use with a deposition apparatus, a sputtering chamber system, and/or ionized plasma deposition system without causing shorts, plasma arcing, interruptions to the deposition process, or particle generation. Improvements in components for use in deposition apparatus are desired.

### SUMMARY

Disclosed herein is a sputtering chamber component comprising a particle trap, the particle trap comprising a patterned macrotexture formed on at least a portion of a surface of the particle trap. The patterned macrotexture has indentations having a depth and is arranged in a repeating pattern. The patterned macrotexture has first threads extending in a first direction, the first threads forming side walls separating adjacent indentations in a second direction. The patterned macrotexture has second threads extending in a second direction. The second direction is at an angle of greater than 0 and less than 180 degrees to the first direction, the second threads forming side walls separating adjacent indentations in a first direction. The patterned macrotexture has a random pattern microtexture formed on the patterned macrotexture; the microtexture has a height less than the depth of the indentations.

Disclosed herein is a sputtering chamber coil having a particle trap comprising a macrotexture defining a plurality of adjacent indentations formed into a surface. The indentations have a depth defined as the distance from the surface to a bottom of each indentation and a width. Adjacent indentations are separated from one another by side walls. A microtexture is overlaid on the macrotexture. The microtexture has a height less than the depth of the indentations.

Also disclosed herein is a method of forming a particle trap on a sputtering chamber component. The method comprises forming a first surface texture having a pattern of indentations formed into a first surface with adjacent indentations separated from each other by side walls, the indentations having a depth and a width. The method also includes forming a second surface texture on the first surface texture. The second surface texture is random and has an average height less than the depth of each indentation of the plurality of patterned indentations.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a top view of an exemplary coil that may be used in a sputtering apparatus.

FIG. 2 is a side view of an exemplary coil that may be used in a sputtering apparatus.

FIG. 3 is a micrograph showing an example knurling pattern that may be used on a particle trap, according to some embodiments.

FIG. 4 is a micrograph of a comparative example of a knurling pattern that may be used on a particle trap.

FIG. 5 is a schematic view of an example knurling pattern that may be used on a particle trap, according to some embodiments.

FIG. 6 is a schematic view of a comparative example of a knurling pattern that may be used on a particle trap.

FIG. 7 is a schematic view of an example knurling pattern that may be used on a particle trap, according to some embodiments.

FIG. 8 is a micrograph showing an example knurling pattern that may be used on a particle trap, according to some embodiments.

FIG. 9 is a micrograph of a comparative example of a knurling pattern.

FIG. 10 is a micrograph showing an example knurling pattern that may be used on a particle trap, according to some embodiments.

FIG. 11 is a micrograph of a comparative example of a knurling pattern.

FIG. 12 is a micrograph showing an example knurling pattern that may be used on a particle trap, according to some embodiments.

FIG. 13 is a micrograph of a comparative example of a knurling pattern.

FIG. 14 is a micrograph of an example sputter trap following a knurling treatment, according to some embodiments.

FIG. 15 is a micrograph showing the sputter trap of FIG. 14 following a surface treatment, according to some embodiments.

FIG. 16 is a flow chart showing an example method of forming a particle trap, according to some embodiments.

### DETAILED DESCRIPTION

Disclosed herein is a particle trap that may be used in a physical vapor deposition apparatus. The particle trap may be used to prevent contaminating particles from redepositing on a substrate within the physical deposition apparatus. Also disclosed herein is a coil having a particle trap for use in a physical vapor deposition apparatus. Also disclosed herein is a method of forming a particle trap on a coil for use in a physical vapor deposition apparatus. In some embodiments, the particle trap may include a surface that has indentations or indentations formed into the surface. The indentations or indentations may be formed in a patterned arrangement along the surface. In some embodiments, the particle trap may include a surface that has indentations or indentations formed into the surface to form a macrotexture, and the particle trap may further include a microtexture formed on the macrotexture.

In some embodiments, the particle trap may be formed along the surface of a coil that may be used in a physical vapor deposition apparatus. In some embodiments, a sputtering coil may have a surface texturing including a macrotexture defining a first surface roughness and a microtexture defining a second surface roughness. The macrotexture may comprise an inverted knurled or female knurled pattern having indentations or indentations. The microtexture may comprise any one of a chemical etched, plasma etched, grit blasted, particle blasted, or wire brushed pattern that adds further to the surface of the coil. The surface texturing can be applied to coils, targets, shielding, bosses, and any surfaces within the sputtering chamber that are exposed to sputtering plasma and could thus contribute to particulate generation.

During a sputtering process, sputtered particles are ejected into the gas phase and may deposit on any surface in the sputtering chamber. Over time, these deposits build up and may become dislodged during a sputtering process, forming particulates. The particulates may then re-deposit on the substrate, leading to contamination of the substrate. A particle trap prevents sputtering particles from re-depositing, or contaminating particles from forming, during sputtering. To improve the useful life of components used within the sputtering chamber, sputtering chamber components can be modified to function as sputtered material re-adhesion sites and particle traps. For example, a material adhesion site or particle trap may include a specifically patterned surface that reduces particle flaking by increasing surface area and mechanical keying to the surface while eliminating flat and angular surfaces.

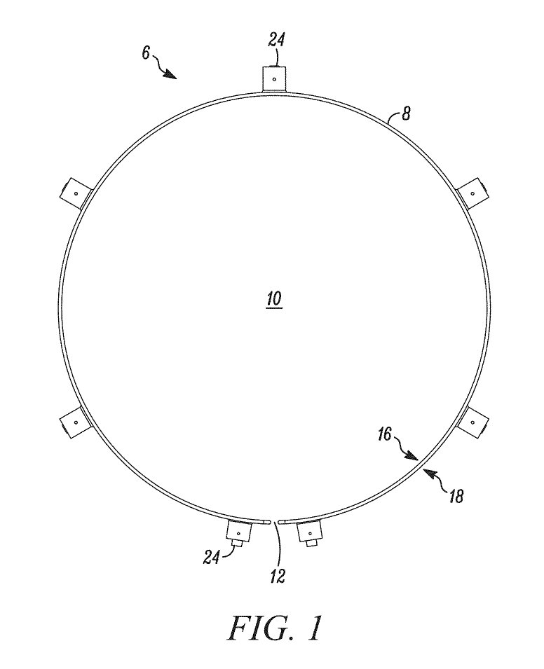

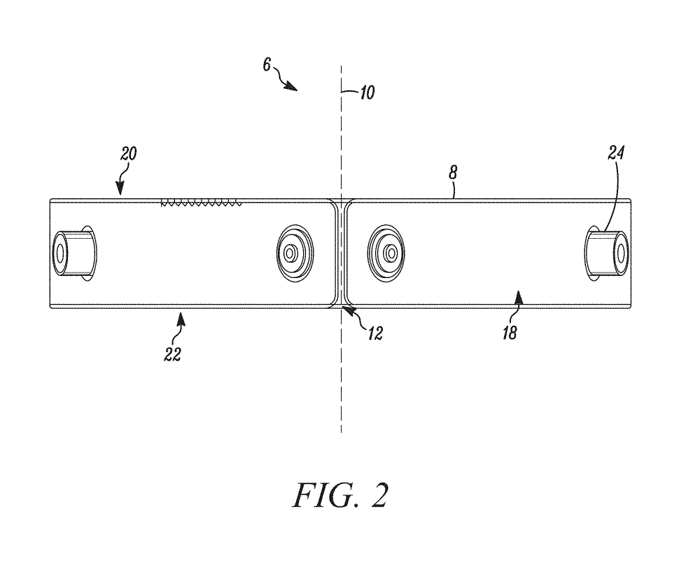

FIG. 1 is a top view of a sputtering coil 6 that may be used in a physical vapor deposition apparatus such as a sputtering chamber. FIG. 2 illustrates the sputtering coil 6 of FIG. 1 as viewed from the side. As shown in FIGS. 1 and 2, the sputtering coil 6 may include a ring 8 that may be substantially circular. The ring 8 has a central axis 10 and a circumference of the ring is defined around the central axis 10. In some embodiments, the sputtering coil 6 may be formed as a ring 8 with a gap 12 in the circumference. For example, the ring 8 may have a first end and a second end which are spaced apart by the gap 12. The sputtering coil 6 may have an inside surface 16 facing radially inward toward the central axis 10 of the ring 8. The sputtering coil 6 may have an outside surface 18 facing radially away from the central axis 10 of the ring 8.

As shown from the side view of FIG. 2, the sputtering coil 6 may have a top surface 20 for example, a surface of the sputtering coil 6 that lies in a plane perpendicular to the central axis 10 of the ring 8. In some embodiments, during a sputtering operation, the top surface 20 may face in the direction of a sputtering target. The sputtering coil 6 may have a bottom surface 22, for example, a surface of the sputtering coil 6 that lies in a plane perpendicular to the central axis 10 of the ring 8 and opposite the top surface 20. During a sputtering operation, the bottom surface 22 may be oriented to face in the direction of the substrate or away from the sputtering target. In some embodiments, the sputtering coil 6 may include additional components, such one or more bosses 24 attached to the sputtering coil 6. For example, bosses 24 may extend radially from the outside surface 18. The bosses 24 may be used to hold the sputtering coil 6 in place in a sputtering apparatus. In some embodiments, at least a portion of a surface of the sputtering coil 6 may have a particle trap formed on it.

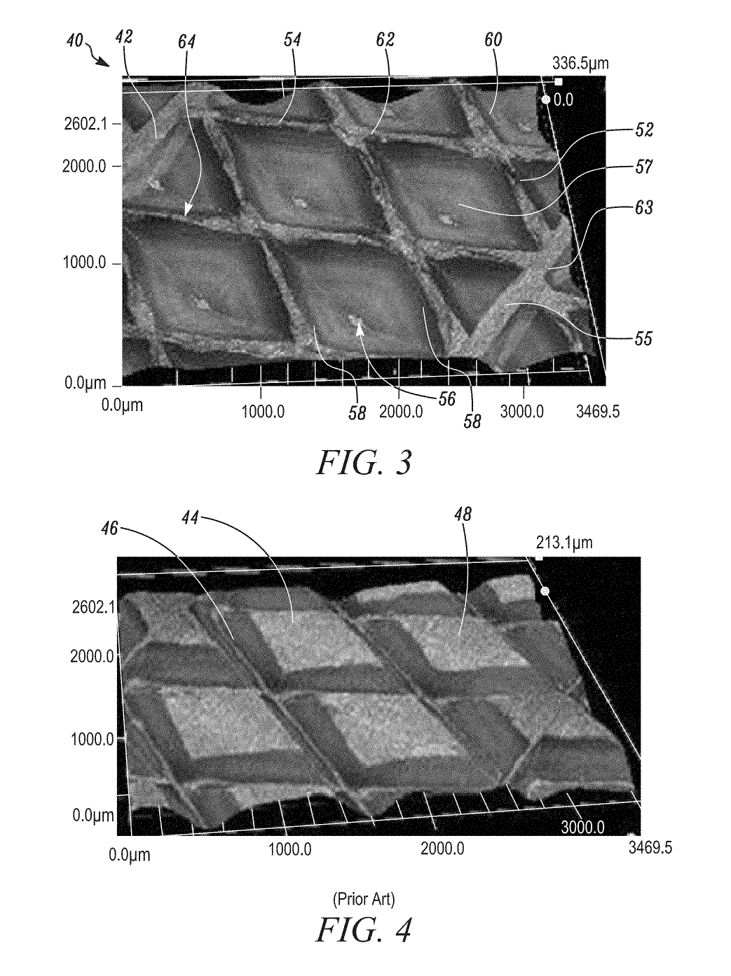

FIG. 3 shows an exemplary embodiment of a particle trap 40 that may be formed on a surface of a sputtering chamber component. Suitable sputtering chamber system components may include targets, target flanges, target sidewalls, shields, cover rings, coils, cups, pins and/or clamps, and other mechanical components. In some embodiments, the sputtering chamber component is formed from titanium (Ti), aluminum (Al), copper (Cu), tantalum (Ta), nickel (Ni), cobalt (Co), molybdenum (Mo), gold (Au), silver (Ag), platinum (Pt), tungsten (W), chromium (Cr), a Ti alloy, an Al alloy, a Cu alloy, a Ta alloy, a Ni alloy, a Co alloy, a Mo alloy, a Au alloy, a Ag alloy, a Pt alloy, a W alloy, or a Cr alloy. In some embodiments, the sputtering chamber component is formed from tantalum. As shown in FIG. 3, in some embodiments, the particle trap 40 may include a macrotexture 42 formed on at least a portion of the surface of the sputtering chamber component. In some embodiments, the macrotexture 42 may form a patterned surface. In some embodiments, the macrotexture 42 may include a particular knurled pattern referred to herein as an inverted knurl or a female knurl. FIG. 4 is included as a comparative example to show a comparison with the inverted knurl in FIG. 3. In some embodiments, the pattern shown in FIG. 4 may be referred to as a projected knurl or male knurl.

As shown in FIG. 3, in some embodiments, the macrotexture 42 includes first threads 52 oriented in a first direction. In some embodiments the macrotexture 42 includes second threads 54 oriented in a second direction. In some embodiments, the macrotexture 42 includes indentations 56 having a bottom 57 and side walls 58 extending up or away from the bottom 57. In some embodiments, the first threads 52 and second threads 54 may be formed in a repeating pattern. For example, first threads 52 may be evenly or substantially evenly spaced apart from adjacent first threads 52 and/or second threads 54 may be evenly or substantially evenly spaced apart from adjacent second threads 54. In some embodiments, indentations 56 are defined between the first and second threads 52, 54 in a repeating adjacent pattern.

In some embodiments, the first threads 52 may include a top 60. For example, a side wall 58 may extend between the bottom 57 of indentations 56 and the top 60 of a first thread 52. The second threads 54 may include a top 62. For example, a side wall 58 may extend between the bottom 57 of indentations 56 and the top 62 of a second thread 54. In this way, indentations 56 are formed between first threads 52 and second threads 54. In some embodiments, tops 60, 62 of first and second threads 52, 54 may form the outermost location of the macrotexture 42 and/or the particle trap 40. In some embodiments, tops 60, 62 of the first and second threads 52, 54 may form an outermost part of the particle trap 40 of a sputtering chamber component having any suitable shape. In some embodiments, the tops 60, 62 of the first and second threads 52, 54, may lie in or may substantially lie in a plane.

The tops 60, 62 of the first and second threads 52, 54 may define a first surface 64 of sputtering chamber component and the indentations 56 are indentations or holes into the thickness of the sputtering chamber component below the first surface 64. The first threads 52 and second threads 54 have a length and width, in which the length is measured in the direction in which the thread extends and the width is measured in direction perpendicular to the length. For example, the length of the first threads 52 is in the first direction and the length of the second threads 54 is in the second direction. In some embodiments, the indentations 56 length may be greater than the width. In some embodiment, the indentations may have substantially equal length and width. For example, the indentations may have a square or substantially square cross-sectional shape. In some embodiments, the first direction that first threads 52 are oriented at may be at an angle from the second direction that the second threads 54 are oriented at.

The indentations 56 have a surface area defined between first and second threads 52 54. The surface area of indentations 56 includes a surface area of the sidewalls 58 and a surface area of the bottom 57 of indentations. The first and second threads 52 54 have a surface area defined along the tops 60, 62 of the first and second threads 52, 54, respectively. The surface area of the indentations 56 is greater than the surface area of the tops 60, 62 of the first and second threads 52 54. The indentations 56 may have any suitable shape or size as defined by the first and second threads 52, 54.

As shown in FIG. 3, in some embodiments, tracks 55 may be present along sputtering chamber component. Tracks 55 may be present along particle trap 40 and may be between indentations 56 and/or first and second threads 52, 54. Tracks 55 may be formed when indentations 56 are formed using a tool that requires multiple passes, such as a roller with a width less than the width of the sputtering chamber component. Tracks 55 may extend in a direction corresponding to a direction traveled by the tool when used to form indentations 56. Tracks 55 formed by a tool may vary in location, depending on the tool width. That is, first and second threads 52, 54 that have the same dimensions over the surface of the sputtering chamber component and a distance between tracks 55 may vary depending on the width of the tool used to form indentations 56. Tracks 55 may have a top 63. In some embodiments, tops 63 of tracks 55 may be the same height as tops 60, 62 of the first and second threads 52, 54. In some embodiments, the particle trap 40 may include only first and second threads 52, 54. That is, the particle trap 40 may be formed by a tool that is at least as wide as the sputtering chamber component and may form indentations 56 in a single pass.

FIG. 4 is a micrograph of a prior art particle trap having a projected knurl or male knurl. For example, a projected knurl may include projections 44 that extend up or away from the surface of the sputtering chamber component. The projections 44 may be separated by grooves 46 or valleys. In some embodiments, the top 48 of projections 44 may be flat or substantially flat such that projections 44 are plateaus. In some embodiments, the projected knurl shown in FIG. 4 may be formed by creating grooves 46 in a flat surface with, for example, a cutting tool. For example, a cutting tool may be pressed along a flat surface to cut or form the grooves 46 into the flat surface and form the projections 44.

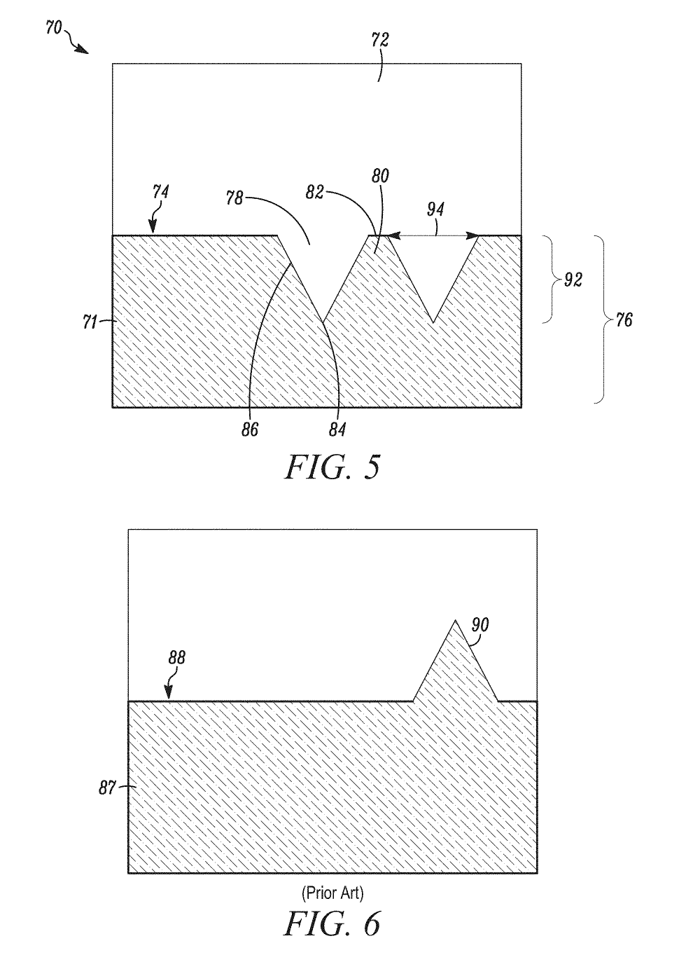

FIG. 5 is a cross-sectional schematic illustration of a particle trap 70 showing the macrotexture 72. As shown in FIG. 5, the outermost parts of the particle trap 70 may define a first surface 74. In some embodiments, a plane drawn along the first surface 74 may define a first plane, and the macrotexture 72 may be formed as indentations 78 into the first surface 74 below the first plane. FIG. 6 shows a comparative example of a projected knurl or male knurl macrotexture formed on a surface 88 of a sputtering chamber component 87. In the comparative example shown in FIG. 6, the sputtering chamber component 87 has a knurling pattern in which projections 90 protrude or extend above the surface 88.

As shown in the cross sectional view of FIG. 5, in some embodiments, the particle trap 70 may be formed on the outside of a sputtering chamber component 71, such as into the first surface 74. In some embodiments, the particle trap may be formed into a thickness 76 of the sputtering chamber component 71. For example, the particle trap 70 may include a macrotexture 72 formed along the sputtering chamber component 71 by forming indentations 78 into the thickness 76 of the outside of the sputtering chamber component 71. The indentations 78 may be defined into the thickness 76 of the sputtering chamber component 71, and have threads 80 separating adjacent indentations 78 from the others. In some embodiments, the threads 80 may have tops 82. The tops 82 of the threads 80 may define an outermost location of the sputtering chamber component 71 along at least a portion of the sputtering chamber component 71. For example, the tops 82 of the threads may be substantially the outermost location of the sputtering chamber component and in combination may define first surface 74 that may lie in a first plane. In some embodiments, particle trap 70 may be formed on a sputtering coil.

As shown in FIG. 5, indentation 78 may have a bottom 84. In some embodiments, the bottom 84 of indentation 78 may be the location of indentation 78 that is farthest from the outer most portion of the sputtering chamber component 71. In some embodiments, the bottom 84 of indentation 78 may be pointed, rounded, curved, flat, or any suitable shape. In some embodiments, the bottom 84 of indentation 78 may be smooth or substantially smooth and in other embodiments, the bottom 84 of indentation 78 may be textured. For example, indentation 78 may be shaped as an inverted cone or an inverted pyramid with the base of the inverted pyramid corresponding to tops 82 of threads 80 and the top of the inverted pyramid corresponding to the bottom 84 of indentation 78. In some embodiments, indentation 78 may be shaped as a frustum, such as a pentagonal, square, or conical frustum, with the widest base of the frustum corresponding to tops 82 of threads 80 and the clipped or narrow base forming a flattened bottom of indentation 78.

As shown in FIG. 5, indentations 78 have a width 94. In some embodiments, the width 94 of indentations 78 may be defined as an interior diameter of the indention 78 between the side walls 86. In some embodiments, the width 94 of indentations 78 may be the greatest distance across the indentation 78 in any direction.

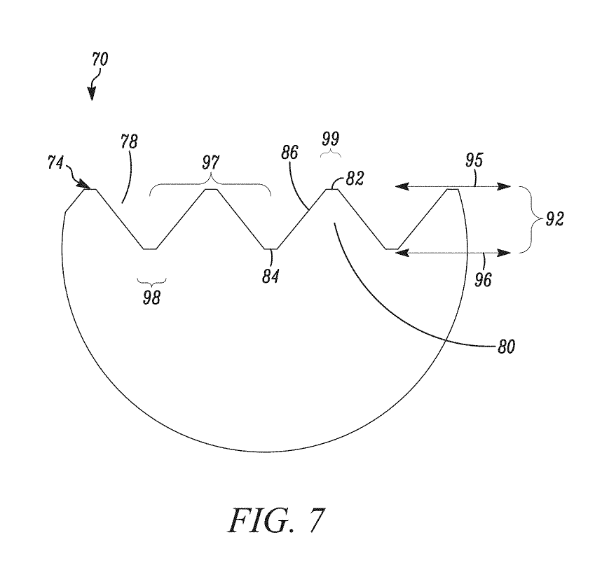

FIG. 7 is a schematic of the particle trap 70 shown in FIG. 5, showing additional features of the macrotexture 72 of FIG. 5 according to some embodiments. As shown in FIG. 7, tops 82 of threads may lie in a first plane 95. Bottoms 84 of indentations 78 may lie in a second plane 96.

In some embodiments, the tops 82 of the threads 80 may have a width 99. In some embodiments, the width 99 of tops 82 of the threads 80 may be as small as about 100 μm, 125 μm, 150 μm, or about 175 μm, or as great as about 200 μm, 250 μm, 275 μm, or 300 μm, or between any pair of the foregoing values. In some embodiments, the bottom 84 of each indentation 78 may have a width 98. In some embodiments, the width 98 of the bottom 84 of each indentation 78 may be as small as about 60 μm, 100 μm, 125 μm, or about 200 μm, or as great as about 300 μm, 400 μm, 500 μm, or 600 μm, or between any pair of the foregoing values.

As shown in FIG. 7, side walls 86 may extend between the tops 82 of threads 80 and the bottom 84 of indentation 78. In some embodiments, indentation 78 may have three side walls, four side walls, or five or more side walls, depending on the shape of the indentation 78. In some embodiments, side walls 86 may be perpendicular or substantially perpendicular to a plane defined by tops 82 of threads 80, such as first plane 95. In some embodiments, side walls 86 may be perpendicular or substantially perpendicular to a plane defined by bottoms 84 of indentations 78, such as a second plane 96. In some embodiments, the side walls 86 may be formed at an angle to tops 82 as small as about 1°, 10°, 15°, or 30°, or as great as about 45°, 60°, 80°, or about 90°, or between any pair of the foregoing values. That is, side walls 86 may be formed at an angle to first plane 95 as small as about 1°, 10°, 15°, or 30°, or as great as about 45°, 60°, 80°, or about 90°, or between any pair of the foregoing values. In some embodiments, the side walls 86 may be formed at an angle to bottom 84 as small as about 1°, 10°, 15°, or 30°, or as great as about 45°, 60°, 80°, or about 90° from the bottom, or between any pair of the foregoing values. That is, side walls 86 may be formed at an angle to second plane 96 as small as about 1°, 10°, 15°, or 30°, or as great as about 45°, 60°, 80°, or about 90° from the bottom, or between any pair of the foregoing values. In some embodiments, side walls 86 may be curved in relation to the first plane 95.

In some embodiments, tops 82 of threads 80 may define a plane that is curved. That is first plane 95 may be curved. In embodiments having first plane 95 that is curved, a depth 92 of indentations 78 may be the maximum distance between first plane 95 and bottom 84 of indentation. The particle trap 70 may have an average depth which may be defined as the average depth 92 of the indentations 78. In some embodiments, the depth 92 of indentation 78 and/or the average depth of the indentations 78 may be as small as about 300 μm, 325 μm, 350 μm, or 375 μm, or as great as about 400 μm, 550 μm, 600 μm, or 650 μm, or between any pair of the foregoing values.

In some embodiments, indentations 78 may define a repeating unit 97. For example, each repeating unit 97 may be defined from a suitable location on an indentation 78 to a similar location on the adjacent indentation 78. In some embodiments, each repeating unit 97 may have a width.

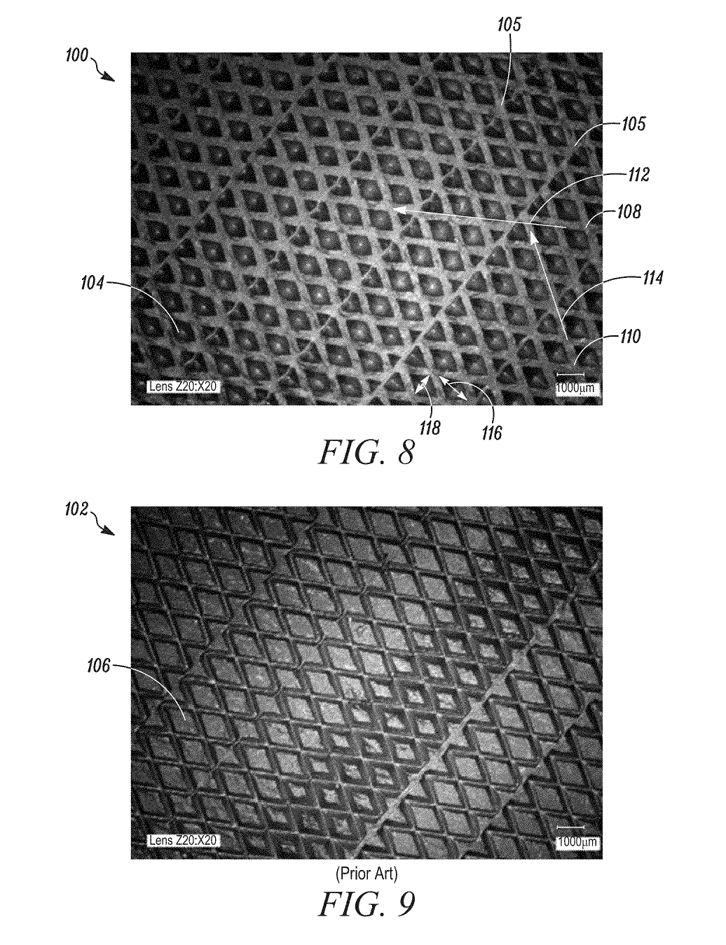

FIG. 8 is a top-down image of an example particle trap 100 formed on the surface of a sputtering coil. The particle trap 100 shown in FIG. 8 has a macrotexture formed of an inverted knurl or female knurl with indentations 104 or indentations. FIG. 9 shows a comparative surface 102 having a projected knurl or male knurl. The comparative surface 102 shown in FIG. 9 has projections 106 protruding from the comparative surface 102.

As shown in FIG. 8, the particle trap 100 may include indentations 104. In some embodiment the indentations 104, may be defined by first threads 108 and second threads 110. In some embodiments, first threads 108 may extend in a first direction as shown by the arrow 112. In some embodiments, second threads 110 may extend in a second direction as shown by the arrow 114. In some embodiments, tracks 105 may be formed by a tool used to form the indentations. Tracks 105 may be formed when indentations 104 are formed using a tool that requires multiple passes, such as a roller with a width less than the width of the sputtering chamber component.

In some embodiments, first and second threads 108, 110 may be formed with a suitable distance between adjacent respective threads when measured in a direction perpendicular to adjacent respective threads. For example, first threads 108 may be formed with a suitable distance between adjacent threads, when measured in a second direction shown by the arrow 114. In some embodiments, second threads 110 may be formed with a suitable distance between adjacent threads, when measured in a first direction shown by the arrow 112.

In some embodiments, the particle trap 100 may have a first thread count of as low as about 15 threads per inch (TPI) (6 first threads per cm), 20 TPI (8 first threads per cm), or 25 TPI (10 first threads per cm), or as great as about 35 TPI (14 first threads per cm), 40 TPI (16 first threads per cm), or 50 TPI (20 first threads per cm), or between any pair of the forgoing values, when measured in a direction perpendicular to first threads 108 (i.e., first threads 108 per inch). Additionally, the particle trap 100 may have a second thread count of as low as about 15 threads per inch (TPI) (6 second threads per cm), 20 TPI (8 second threads per cm), or 25 TPI (10 second threads per cm), or as great as about 35 TPI (14 second threads per cm), 40 TPI (16 second threads per cm), or 50 TPI (20 second threads per cm), or between any pair of the forgoing values, when measured in a direction perpendicular to second threads 110 (i.e., second threads 110 per inch).

As shown in FIG. 8, indentations 104 are a four-sided figure such as a parallelogram, when viewed in a direction normal to the surface of the sputtering coil. A repeated pattern formed by adjacent parallelogram indentations 104, in combination, may form an overall patterned surface that may be a repeated parallelogram. The repeated pattern formed by adjacent parallelogram indentations 104 side by side over a surface may form an overall patterned surface known as a parallelogram close-packed pattern. As shown in FIG. 8, when viewed from above (i.e., a direction perpendicular to the plane of the particle trap 100), indentations 104 may have a diamond shape, with four corners. In some embodiments, two corners of the four corners may have a first angle, and the two remaining corners of the four corners may have a second angle. For example, in some embodiments, indentations 104 may be a diamond shape, with two corners having an angle as low as about 1°, 15°, or 30°, or as great as about 45°, 60°, or 90°, or between any pair of the foregoing values. Although described as a parallelogram, indentations 104 may be any suitable shape when viewed in a direction normal to the surface of the particle trap 100 such as circle, oval, square, rectangle, parallelogram, pentagon, hexagon, honeycomb, or any other shape.

Indentations 104 have a width. For example, indentations 104 may have a width that is defined as the farthest distance across the indentation 104. In some embodiments, indentations 104 may have a width that is defined as the distance across the indention 104 in a particular direction. For example, as shown in FIG. 8, indentations 104 may have a diamond shape when viewed in the direction normal to the first plane of the particle trap 100. In some embodiments, indentations 104 may have a width measured at the longest distance of indentations 104, for example between two corners that are farthest apart, shown by arrow 116. In some embodiments, indentations 104 may have a width measured between two corners that are the shortest distance apart, such as shown by arrow 118.

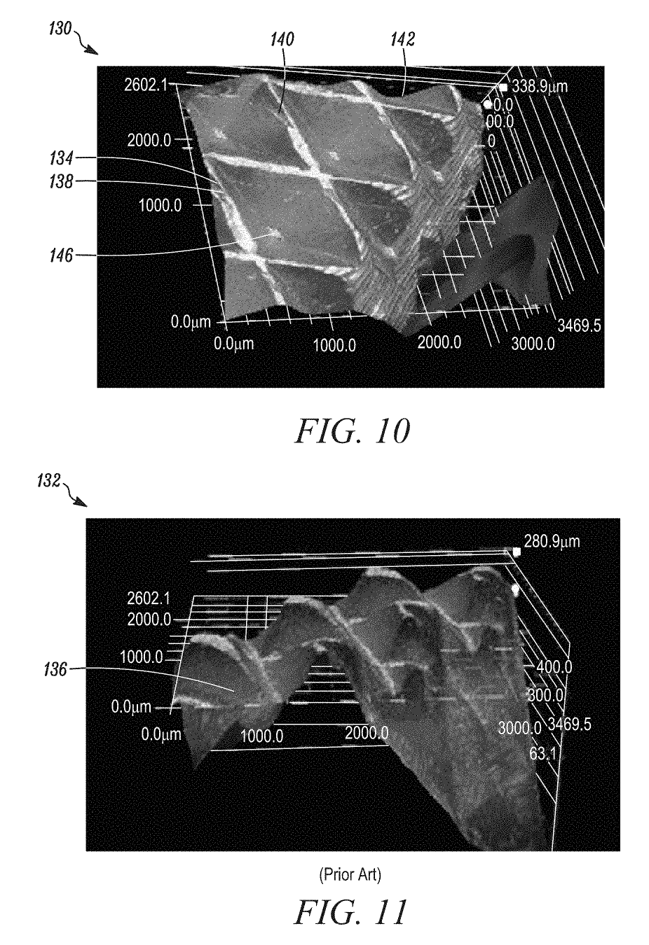

FIG. 10 is a micrograph showing an example particle trap 130 that includes an inverted knurl 134 that was formed on a substantially flat surface of a sputtering coil, such as a surface forming the outside surface 18 or inside surface 16 of a sputtering coil as shown FIG. 1. FIG. 11 is included as a comparative example of a particle trap 132 having a having projected knurl 136 formed on the surface of a sputtering coil.

As shown in FIG. 10, a particle trap 130 was formed with indentations 138 as diamond shaped inverted pyramids. As shown in FIG. 10, the particle trap 130 was formed by first threads 140 extending in a first direction, and second threads 142 extending in a second direction. The tops of the first and second threads 140, 142 define the surface of the particle trap 130 with the base of each inverted pyramid corresponding to the surface of the coil. The apex of each inverted pyramid was oriented into the thickness of the sputtering coil and defines the bottom 146 of each indentation 138. The measured depth of each indentation 138 was between about 336 μm and about 338 μm. The thread count of the particle trap was measured in the direction perpendicular to the threads. The first thread count was measured to be 25 TPI (10 threads per cm).

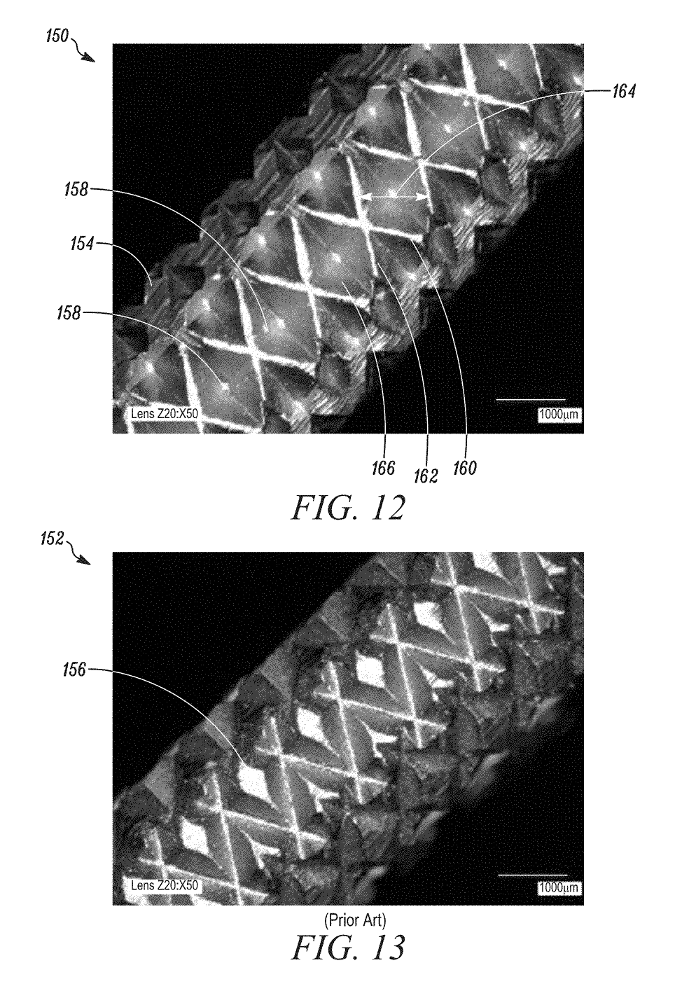

FIG. 12 is a micrograph showing an example particle trap 150 that includes an inverted knurl 154 that was formed on an a curved surface of a sputtering coil, such as a surface forming a side along the top surface 20 or the bottom surface 22 of a sputtering coil as shown FIG. 2. FIG. 13 is included as a comparative example of a particle trap 152 having a projected knurl 156 formed on the curved surface of a sputtering coil.

As shown in FIG. 12, a particle trap 150 was formed with indentations 158 as diamond shaped inverted pyramids. As shown in FIG. 12, the particle trap 150 was formed by first threads 160 extending in a first direction, and second threads 162 extending in a second direction. The shape of the indentations 158 was an inverted pyramid oriented into the thickness of the coil, with the top of the pyramid defining the bottom 168 of the indentation 158. The measured depth of the indentations 158 was between about 336 μm and about 338 μm. The thread count of the particle trap, as measured in the direction shown by arrow 164, was 25 TPI (10 threads per cm). The particle trap 150 had side walls 166 extending between the tops of the first and second threads 160, 162 and the bottom 168 of each indentation.

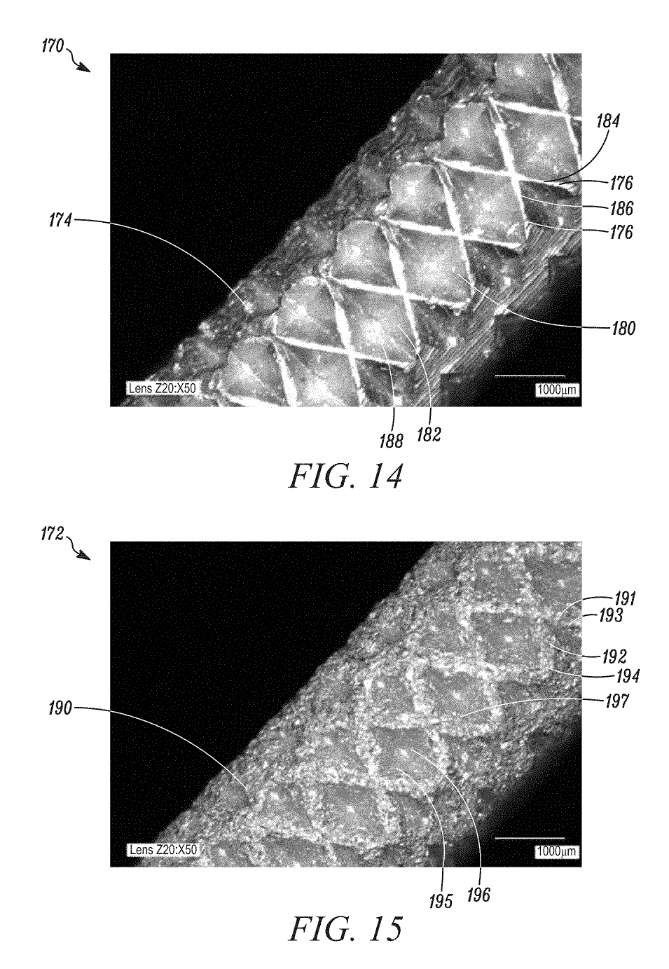

FIG. 14 is a micrograph image showing a macrotexture 170 before a microtexture has been added. FIG. 15 is a micrograph image showing the macrotexture 170 of FIG. 14 after a microtexture 190 has been added. That is, FIG. 14 shows an inverted knurl 174 formed on a curved surface of a sputtering coil; and FIG. 15 shows the inverted knurl 174 shown in FIG. 14, after additional processing.

As shown in FIG. 14, an inverted knurl 174 has first threads 176, second threads 178, side walls 180, and indentations 182. In some embodiments, following the formation of the inverted knurl 174, the inverted knurl 174 may include sharp or pointed edges. For example, sharp or pointed edges may be present on top 184, 186 of the first and second threads 176, 178, respectively. Additionally or alternatively, the side walls 180 and/or bottom 188 of each indentation 182 may be substantially smooth. That is, as shown in FIG. 14, after the inverted knurl 174 has been formed, the side walls 180 and/or bottom 188 may be relatively even, and not have a texture, such as a microtexture, overlaid onto the side walls 180 and/or bottom 188.

FIG. 15 shows the macrotexture 170 of FIG. 14 after the inverted knurl 174 has undergone or been treated with an additional surface treatment to add a microtexture 190 on the inverted knurl 174. The resulting particle trap 172 is an inverted knurl 174 having a microtexture 190 overlaid onto the inverted knurl. In some embodiments, the roughness or microtexture is present over the entire macrotexture 170, such as over the inverted knurl 174 described with reference to FIG. 14.

As shown in FIG. 15, the microtexture 190 may provide a rough surface with the pointed or sharp edges along the tops 184, 186 of the first and second threads 176, 178 from FIG. 14 broken up. For example, a roughened or abraded surface forming a microtexture 190 is located along tops 191, 192 of first and second threads 193, 194 in FIG. 15. Side walls 180 and bottom 188 of the indentations 182 in FIG. 14 are roughened and abraded to form side walls 195 and bottom 196 of indentation 197 having microtexture in the particle trap 172 shown in FIG. 15. That is, as shown in FIG. 15, after a microtexture 190 has been added to the inverted knurl, rather than a smooth or planar surface on the side walls 180 and bottom 188 of the indentations 182 in FIG. 14, there is a rough undulating surface containing a microtexture 190 with rises and craters. In some embodiments, breaking up the smooth surfaces, or sharp edges may increase the surface area of the particle trap 172 and provide a larger area for particles to adhere to during a sputtering process. In some embodiments, a surface having a rough texture such as a microtexture 190 formed on a macrotexture, such as an inverted knurl, provides better adhesion of particles compared to a surface that does not have a microtexture 190.

In some embodiments, a macrotexture, such as the inverted knurl 174 shown in FIG. 14 may have a suitable depth that can be measured by use of a laser confocal microscope. For example, a microscope may be used to measure an average height by taking individual measurements as the microscope is moved along the surface of the macrotexture in a direction from out of focus below the bottom of each indentation to out of focus over the top of the threads. The measurements may be analyzed by defining a first plane corresponding to the tops of the threads and a second plane with points at the bottom of the indentations, such as first and second planes 95, 96 described with reference to FIG. 7. A suitable confocal microscope that may be used to measure the depth of the inverted knurl is a Keyence Color 3D Laser Confocal Microscope model VK9710, using mode VHX 2000. In one example, a macrotexture was created that had a measured average height of 420 μm.

In some embodiments, the surface area of the inverted knurl comprises the combined area of the first threads 176, second threads 178, side walls 180, and indentations 182 shown in FIG. 14. This combined surface area is greater than a substantially flat or planar surface, such as an area prior to knurling or other surface patterning or texturization. In some embodiments, the height of the macrotexture may be defined using an arithmetic mean surface roughness (Ra) as defined by various international standards that can be measured. In some embodiments, the surface roughness (Ra) of the macrotexture may be defined by an average of the distance between the bottom 188 of each indentation 182 and the highest point on the tops 184, 186 of first and second threads 176, 178 in FIG. 14. The arithmetic surface roughness (Ra) may be measured both before a microtexture 190 is added to the macrotexture, such as in FIG. 14, and after a microtexture 190 has been added, such as in FIG. 15, to determine a difference in mean surface roughness of the macrotexture. In some embodiments, the microtexture 190 may have a roughness or height that may be measured as a roughness or height above a surface of the macrotexture.

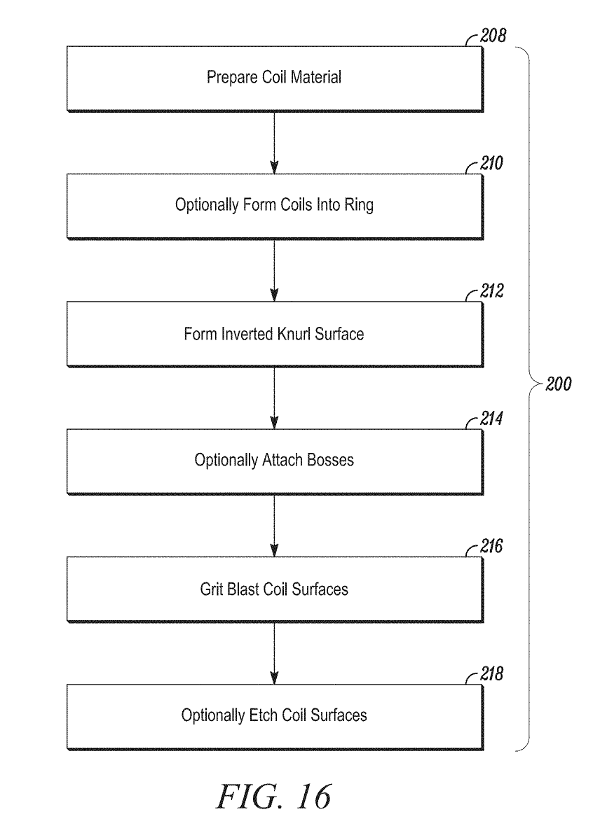

FIG. 16 is a flow chart of method 200 of forming a particle trap on a sputtering coil. A sputtering trap is formed in step 208. For example, the sputtering coil material may be punched or pressed from a master material to form a flat coil that will later be shaped. In some embodiments, the coil material may first be formed into strips or lengths of material. The prepared coil material may optionally be formed into a ring in step 210. In general, the ring may be a substantially complete circle. In some embodiments, a gap may be formed in the coil after the coil is formed into a ring. In some embodiments, step 210 may alternatively be carried out after any of steps 212, 214, or 216. In some embodiments, sputtering coil is formed from titanium (Ti), aluminum (Al), copper (Cu), tantalum (Ta), nickel (Ni), cobalt (Co), molybdenum (Mo), gold (Au), silver (Ag), platinum (Pt), tungsten (W), chromium (Cr), a Ti alloy, an Al alloy, a Cu alloy, a Ta alloy, a Ni alloy, a Co alloy, a Mo alloy, a Au alloy, a Ag alloy, a Pt alloy, a W alloy, or a Cr alloy. In some embodiments, the sputtering coil is formed from tantalum.

In some embodiments, the coil material may undergo a macrotexture forming process in step 212, such as knurling the surface of the coil material. Step 212 may include adding an inverted knurl, such as an inverted knurl described above with reference to FIG. 3, 8, 12, or 14. Suitable tools or subtractive methods may be used to form a specific inverted knurl pattern having a regular depth. A suitable tool comprises any mechanically patterning tool that achieves a suitable roughness or depth. One suitable method of forming the inverted knurl into the coil material includes pressing a tool having a roller with raises projections to form indentations into a surface when the roller is pressed into the surface. For example, a roller may be used to press the projections into the surface of a coil to form indentations. The width of the tool may vary from less than the width of the surface the roller is being pressed into, to at least as wide as the surface the roller is being pressed into. If the width of the tool is less than the width of the surface the roller is being pressed into, the multiple passes of the tool may be required to process the entire surface and result in tracks between each pass, as shown in FIG. 8. Using multiple passes of the tool, the threads may be aligned in a substantially parallel direction. In some embodiments, the tool might not align during each pass of the tool, resulting in incomplete indentations. For example, with each pass of the tool, partial indentations may be formed along the edge of the tool, as shown in FIG. 8 In some embodiments, an inverted knurl may be applied on a sputtering coil using a knurling roll on both the outer and inner surface at the same time.

In some embodiments, an inverted knurl can be cut into the coil material with a laser. For example, indentations can be cut into the coil with a laser. In some embodiments, applying an inverted knurl to a sputtering chamber component, such as a sputtering coil allows for a greater knurl depth to be formed with the inverted knurl. In turn, a greater surface area may be formed on the sputtering coil using an inverted knurl pattern, compared to alternative patterns.

The coil may optionally have bosses attached to the outer surface in step 214. In some embodiments, bosses may optionally be attached before forming a macrotexture on the coil surface or may be attached after forming a macrotexture. That is, steps 212 and 214 may be carried out in any suitable order.

In some embodiments, a microtexture may be formed over the macrotexture in step 216. The microtexture is characterized by having a random pattern. In some embodiments, forming a microtexture may include any one of grit blasting, wire brushing, or etching such as with chemicals or plasma. Grit blasting may be used to abrade the surface of the macrotexture, create greater surface area, and break up peaks on the macrotexture. For example, a grit blasting step may include grit blasting silicon carbide grit to material having a macrotextured surface to form a microtexture. In some embodiments, silicon carbide grit blasting provides certain advantages, such as the ability to detect residual grit on the surface of the coil after a grit blasting process. In some embodiments, a grit blasting process may be used alone in step 216 or in combination with another surface treatment step. For example, in step 218 an etching step such as chemical etching, may be used in addition to grit blasting. In some embodiments, chemical etching may be used instead of grit blasting to create the microtexture, remove sharp edges from the macrotexture, and adding to the surface area. In some embodiments, an aggressive chemical etch process may be used to create the microtexture. In some embodiments, a chemical etch process may be used after a grit blasting process and may clean the surface of the grit blasting particles that may be left on the particle trap after the grit blasting. An example chemical etching process may include etching with hydrofluoric acid. An example aggressive chemical etch process may include etching with hydrofluoric acid at higher acid concentrations and/or for longer times.

In some embodiments, steps 210, 212, 214, or 216 may be carried out in any order. For example, in some embodiments, bosses may optionally be attached after forming both the macrotexture and the microtexture. In some embodiments, the coil material is formed into a ring after a surface treatment has been applied to the coil material, such as adding a macrotexture and optionally also a microtexture.

After method 200, at least a portion of the sputtering coil surface has a macrotexture. In some embodiments the macrotexture may be an inverted knurl formed into the surface of the sputtering coil. After method 200 is carried out, at least a portion of the coil surfaces may also have a microtexture. In some embodiments, all surfaces of the sputtering coil can be treated with any of the above treatment steps. Additionally, the surfaces of the bosses can also be subjected to these surface texturing steps. In some embodiments the surface roughness of the microtexture may have an Ra value as low as 2 μm, 3 μm, or 5 μm, or as high as 10 μm, 15 μm, or 20 μm, or between any pair of the foregoing values. In some embodiments an average height of the microtexture is from about 2 μm to about 20 μm. In some embodiments the surface roughness of the microtexture may have an Ra value that is a percentage of the Ra value of the macrotexture. For example, the microtexture may have an Ra value that is as low as about 0.1%, 0.5%, or about 1%, to as high as about 3%, 5%, or about 10%, the Ra value of the macrotexture, or any between any pair of the foregoing values. A suitable device that may be used to measure the roughness value is a Keyence Color 3D Laser Confocal Microscope model VK9700.

Sputtering processes may take place within a sputtering chamber. Sputtering chamber system components may include targets, target flanges, target sidewalls, shields, cover rings, coils, cups, pins and/or clamps, and other mechanical components. Often, a coil is present in these systems and/or deposition apparatuses as an inductive coupling device to create a secondary plasma of sufficient density to ionize at least some of the metal atoms that are sputtered from the target. In an ionized metal plasma system, the primary plasma forms and is generally confined near the target by a magnetron, and subsequently gives rise to atoms being ejected from the target surface. The secondary plasma formed by the coil system produces ions of the material being sputtered. These ions are then attracted to the substrate by the field in the sheath that forms at the substrate surface. As used herein, the term “sheath” means a boundary layer that forms between a plasma and any solid surface. This field can be controlled by applying a bias voltage to the substrate. This is achieved by placing the coil between the target and the wafer substrate and increasing the plasma density and providing directionality of the ions being deposited on the wafer substrate. Some sputtering apparatuses incorporate powered coils for improved deposition profiles including via step coverage, step bottom coverage, and bevel coverage.

Surfaces within the sputtering chamber that are exposed to plasma may incidentally become coated with sputtered material deposited on these surfaces. Material that is deposited outside the intended substrate may be referred to as back-sputter or re-deposition. Films of sputtered material formed on unintended surfaces are exposed to temperature fluctuations and other stressors within the sputtering environment. When the accumulated stress in these films exceeds the adhesion strength of the film to the surface, delamination and detachment may occur, resulting in particulate generation. Similarly, if a sputtering plasma is disrupted by an electrical arc event, particulates may be formed both within the plasma, and from the surface that receives the arc force. Coil surfaces, especially those that are very flat or have sharply angular surfaces, may exhibit low adhesion strength resulting in undesirable particulate build up. It is known that particle generation during PVD is a significant cause of device failure and is one of the most detrimental factors that reduce functionality in microelectronic device fabrication.

Deposition of sputtering material can occur on the surfaces of sputtering coils. Coil sets generate particulate matter due to shedding from coil surfaces, especially those that are very flat or have sharply angular surfaces. During a sputtering process, often the particulates from within a sputtering chamber will be shed from the coils. To overcome this, sputtering chamber components can often be modified in a number of ways to improve their ability to function as particle traps and also reduce problems associated with particle formation.

It is desirable to develop high performing coils for use with a deposition apparatus, a sputtering chamber system and/or ionized plasma deposition system without causing shorts, plasma arcing, interruptions to the deposition process, or particle generation. Using the methods disclosed here, improved surfaces for use on a sputtering apparatus coil may be used as a particle trap to improve coil performance.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

The following is claimed:

1. A sputtering chamber component comprising a particle trap, the particle trap comprising:
a patterned macrotexture formed on at least a portion of a surface of the sputtering chamber component, the patterned macrotexture having:
indentations having a depth and arranged in a repeating pattern;
first threads extending in a first direction, the first threads forming side walls separating adjacent indentations in a second direction; and
second threads extending in the second direction, the second direction at an angle of greater than 0 and less than 180 degrees to the first direction, the second threads forming side walls separating adjacent indentations in the first direction; and
a random pattern microtexture formed on the patterned macrotexture, the microtexture having a height less than the depth of the indentations.

2. The sputtering chamber particle trap of claim 1, wherein the patterned macrotexture has a thread count of from about 8 first threads per cm to about 20 first threads per cm.

3. The sputtering chamber particle trap of claim 2, wherein the patterned macrotexture has a thread count of from about 8 second threads per cm to about 20 second threads per cm.

4. The sputtering chamber particle trap of claim 1, wherein the microtexture is formed by at least one of bead blasting, wire brushing, plasma etching, or chemical etching.

5. The sputtering chamber particle trap of claim 1, wherein the indentations have a parallelogram cross-sectional shape in a direction parallel to the surface.

6. The sputtering chamber particle trap of claim 1, wherein an average depth of the indentations is from about 330 μm to about 420 μm.

7. The sputtering chamber particle trap of claim 1, wherein an average height of the random pattern microtexture is from about 2 μm to about 20 μm.

8. The sputtering chamber particle trap of claim 1, wherein the indentations are shaped as inverted pyramids with an apex of an inverted pyramid positioned at a bottom of an indentation.

9. A sputtering chamber coil having a particle trap on at least a portion of a surface of the coil, the particle trap comprising:
a repeating-pattern macrotexture defining a plurality of adjacent indentations indentation formed into at least a portion of a surface of the coil, the indentations having a depth defined as the distance from the surface to a bottom of each indentation and a width, and wherein adjacent indentations are separated from one another by side walls; and
a random-pattern microtexture overlaid on the macrotexture, the microtexture having a height less than the depth of the indentations.

10. The sputtering chamber coil of claim 9, wherein the indentations have an inverted square pyramid shape.

11. The sputtering chamber coil of claim 9, wherein the indentations form a parallelogram close-packed pattern in a direction parallel to the first surface.

12. The sputtering chamber coil of claim 9, wherein the random-pattern microtexture is formed by at least one of bead blasting, wire brushing, plasma etching, or chemical etching.

13. A method of forming a particle trap on a sputtering chamber component, the method comprising:
forming a first surface texture having a repeating pattern of indentations into a first surface of the sputtering chamber component with adjacent indentations separated from each other by side walls, the indentations having a depth and a width; and
forming a second surface texture on the first surface texture, wherein the second surface texture has a random pattern and has an average height less than the depth of each indentation of the plurality of patterned indentations.

14. The method of claim 13, wherein the indentations are shaped as inverted pyramids with the base of each inverted pyramid parallel to the first surface and the apex of each inverted pyramid oriented into the surface and wherein the height of each inverted pyramid defines the depth of each indentation of the plurality of indentations.

15. The method of claim 13, wherein forming the second surface texture includes at least one of grit blasting, wire brushing, plasma etching, or chemical etching.

16. The method of claim 13, wherein an average depth of the indentations is from about 330 μm deep to about 420 μm.

17. The method of claim 13, wherein an average height of the random pattern microtexture is from about 2 μm to about 20 μm.

18. The method of claim 13, wherein the first surface texture is formed by pressing a knurling tool into the surface of the sputtering chamber component to form the pattern of indentations.
